(19) United States
(12) Patent Application Publication
(10) Pub. No.: US 2011/0142577 A1
(43) Pub. Date: Jun. 16, 2011

(54) SEMICONDUCTOR MANUFACTURING PLANT

(75) Inventor: Etsuro YOSHIDA, Tokyo (JP)

(73) Assignee: SUMCO CORPORATION, Tokyo (JP)

(21) Appl. No.: 13/033,936

(22) Filed: Feb. 24, 2011

Related U.S. Application Data
(63) Continuation of application No. PCT/JP2009/066090, filed on Sep. 15, 2009.

(30) Foreign Application Priority Data
Sep. 30, 2008 (JP) 2008-255718
Oct. 2, 2008 (JP) 2008-257685

(51) Int. Cl. H01L 21/677

(52) U.S. Cl. 414/222.01

(57) ABSTRACT

A wafer manufacturing factory manufacturing semiconductor wafers and a device manufacturing factory manufacturing semiconductor devices are provided abutting each other via a conveying zone including a clean room, and the wafers are held by a conveying apparatus to be conveyed from the wafer manufacturing factory to the device manufacturing factory without being stored in a carrying case.

### BACKGROUND OF THE INVENTION

1. Technical Field of the Invention

The present invention relates to a semiconductor manufacturing plant growing semiconductor ingots to manufacture semiconductor wafers and manufacturing semiconductor devices from the semiconductor wafers.

2. Description of the Related Art

Conventional semiconductor wafer manufacturing factory and semiconductor device manufacturing factory are built at locations distant from each other. Wafers having been manufactured in the manufacturing factory for semiconductor wafers are carried, in a packaging appearance as being stored in carrying cases, to the semiconductor device manufacturing factory using a transport vehicle or other means (Patent Document 1: Published Patent Application No. 2005-85913), and the wafers are then taken out from such carrying cases within the semiconductor device factory to be manufactured into semiconductor devices through various processes.

### SUMMARY OF THE INVENTION

However, large diameter wafers having diameters of more than 300 mm, such as 450 mm wafers, are heavy and thus liable to warp thereby being difficult to be handled. As a consequence, at the time of storing wafers into a carrying case or putting out therefrom, or during transportation in a packaging appearance as being stored in a carrying case, wafers may possibly be subject to damages, such as cracking, breaking, and deformation.

An object of the present invention is, therefore, to provide a semiconductor manufacturing plant capable of preventing wafers from damages even though for large diameter wafers.

The present invention achieves the above object through adjacently providing a wafer manufacturing factory manufacturing a semiconductor wafer and a device manufacturing factory manufacturing a semiconductor device via a conveying zone comprised of a clean room, and holding a wafer or wafers by a conveying apparatus to convey the wafer or wafers from the wafer manufacturing factory to the device manufacturing factory without storing the wafer or wafers in a carrying case.

The above object is also achieved by a wafer manufacturing factory provided abutting a device manufacturing factory via a conveying zone comprised of a clean room, the device manufacturing factory manufacturing a semiconductor device from a semiconductor wafer, the wafer manufacturing factory comprising a conveying apparatus provided within the conveying zone and holding the semiconductor wafer manufactured in the wafer manufacturing factory to convey the semiconductor wafer to the device manufacturing factory without storing the semiconductor wafer in a carrying case.

Although the diameter of wafers manufactured in the wafer manufacturing factory is not particularly limited in the above invention, wafers having large diameters, such as 450 mm wafers, may be manufactured.

In the above invention, the wafer manufacturing factory and the device manufacturing factory are built as one building or as different buildings.

In the above invention, the conveying apparatus may be configured to hold only an edge portion of the semiconductor wafer.

In the above invention, the semiconductor manufacturing plant may be configured to further comprise a storage temporarily storing the semiconductor wafer within at least either one of a final process in the wafer manufacturing factory or an initial process in the device manufacturing factory.

In the above invention, the device manufacturing factory may comprise: a device element forming factory creating semiconductor elements on the semiconductor wafer; and a device assembly factory manufacturing semiconductor devices from the wafer having been created with the semiconductor elements, and the device element forming factory and the device assembly factory may be provided abutting each other via a conveying zone comprised of a clean room.

According to the above invention, it is enabled to prevent wafers from damages even though for large diameter wafers.

### BRIEF DESCRIPTION OF DRAWINGS

FIG. 1 is a front elevational view of a semiconductor manufacturing plant according to an embodiment of the present invention;

FIG. 2 is a plan view illustrating the semiconductor manufacturing plant in FIG. 1;

FIG. 3 is a cross sectional view along III-III line in FIG. 2;

FIG. 4A is a plan view illustrating a chuck of a conveying apparatus in FIG. 2;

FIG. 4B is a side elevational view for FIG. 4A; and

FIG. 4C is a side elevational view for explaining the handling operation of the conveying apparatus in FIG. 2.

### DESCRIPTION OF THE PREFERRED EMBODIMENT

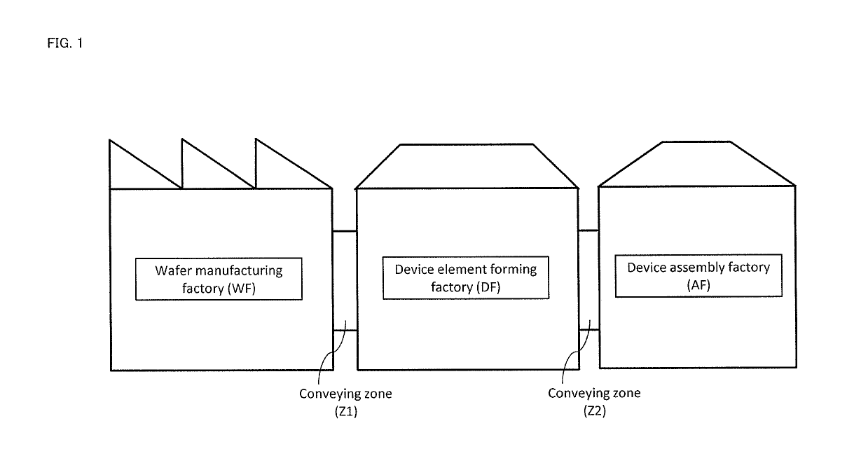

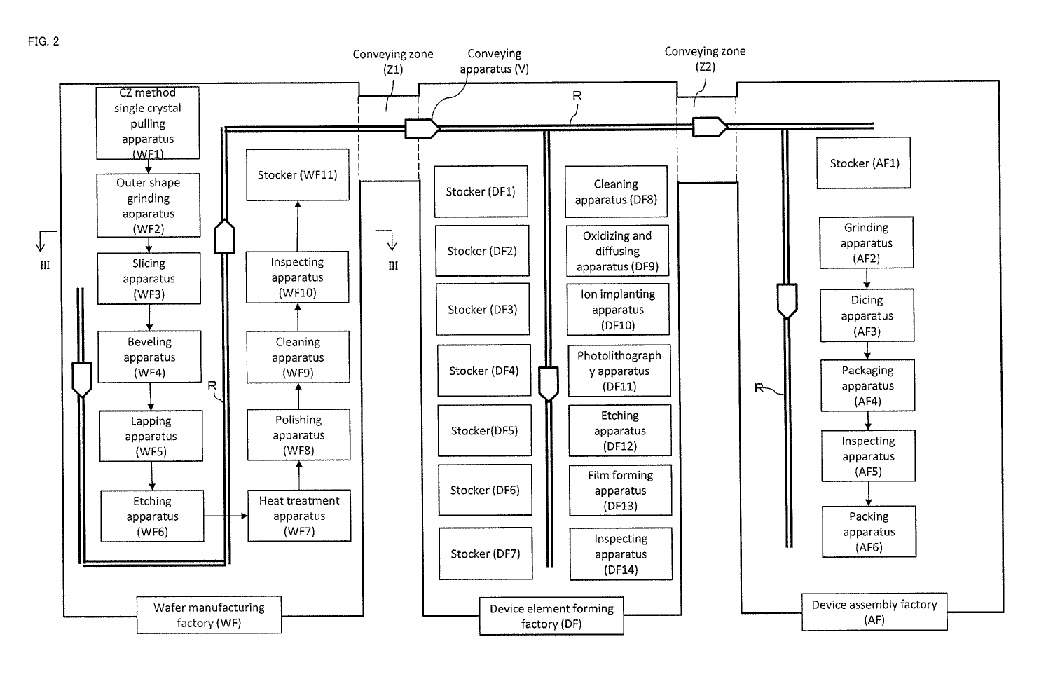

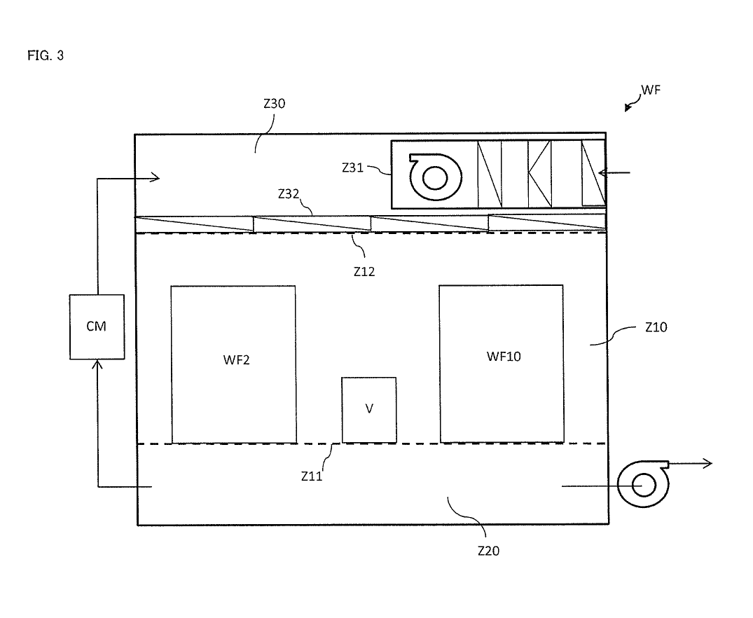

Hereinafter, embodiments of the present invention will be described with reference to the drawings. FIG. 1 is a front elevational view of a semiconductor manufacturing plant according to an embodiment, FIG. 2 is a plan view of the same, and FIG. 3 is a cross sectional view along III-III line in FIG. 2.

The semiconductor manufacturing plant according to the present embodiment comprises a wafer manufacturing factory WF for manufacturing semiconductor wafers and device manufacturing factories DF and AF for manufacturing semiconductor devices, and buildings of the wafer manufacturing factory WF and the device manufacturing factories DF and AF are constructed adjacently to one another. The wafer manufacturing factory WF is connected with the device manufacturing factories DF and AF via a conveying zone Z1 comprised of a clean room.

The device manufacturing factories comprise a device element forming factory DF for creating semiconductor elements to be embedded onto and/or into semiconductor wafers and a device assembly factory AF for manufacturing semiconductor devices from wafers embedded with such semiconductor elements, and the device element forming factory DF and the device assembly factory AF are constructed adjacently to each other. The device element forming factory DF and the device assembly factory AF are connected with each other via a conveying zone Z2 comprised of a clean room.

Alternatively, the device element forming factory DF and the device assembly factory AF may be constructed as a single building. Moreover, the wafer manufacturing factory WF, the device element forming factory DF, and the device assembly factory AF may be built up as a single building.

In the case where the wafer manufacturing factory WF and the device element forming factory DF are constructed as being independent buildings, the distance therebetween is, although not particularly limited, preferably 20 meters or less, and more preferably 10 meters or less. Likewise in the case where the device element forming factory DF and the device assembly factory AF are constructed as being independent buildings, the distance therebetween is, although not particularly limited, preferably 20 meters or less, and more preferably 10 meters or less. If the distance between adjacent two buildings according to the present embodiment is overly long, then the conveying zone Z1 or Z2 comprised of a clean room necessarily comes to be long, thereby being undesirable from the point of running cost for operating the clean room.

Referring now to FIG. 2, configuration example of each factory WF, DF, AF will be explained. It should be appreciated that the example shown in FIG. 2 is not intended to limit the present invention to this but is a representative example, and additional components may be employed or any component disclosed herein may be omitted in appropriate manner.

As shown in FIG. 2, the wafer manufacturing factory WF is arranged with a CZ method (Czochralski method) pulling apparatus WF1, an outer shape grinding apparatus WF2, and a slicing apparatus WF3.

The CZ method pulling apparatus WF1 grows an ingot of silicon single crystal from polycrystal silicon material using CZ method. Although the silicon single crystal grown according to the present embodiment is not particularly limited, preferred is a large diameter one, and more preferred is to be applied to wafers with diameter of more than 300 mm, such as 450 mm wafers.

The outer shape grinding apparatus WF2 grinds the outer shape of a silicon single crystal ingot having been grown, such that the ingot comes to be of cylindrical to have a homogeneous diameter. The slicing apparatus WF3, which is provided as an inner blade cutting machine or a wire saw, slices the silicon single crystal ingot having been ground with its outer shape into desired thicknesses within a certain area of a desired resistivity range. Note that a processing apparatus may be provided to measure the crystal orientation and form an orientation flat or notch after the process by the outer shape grinding apparatus WF2.

Through spaces between the CZ method pulling apparatus WF1 and the outer shape grinding apparatus WF2 and between the outer shape grinding apparatus WF2 and the slicing apparatus WF3, silicon single crystal ingots are conveyed by appropriate conveyers. In contrast, ingots are sliced into wafers after completing the slicing process by the slicing apparatus WF3, and thus one or more wafers are subsequently held by a conveying apparatus V as will be described later and conveyed between respective apparatuses.

Subsequent to the slicing apparatus WF3, there are arranged a beveling apparatus WF4, a lapping apparatus WF5, an etching apparatus WF6, a heat treatment apparatus WF7, a polishing apparatus WF8, a cleaning apparatus WF9, and an inspecting apparatus WF10.

The beveling apparatus WF4 performs beveling process for circumference surfaces of wafers in order to prevent wafers from breaking or cracking because silicon wafers are rigid and inherently brittle. The lapping apparatus WF5, which is an apparatus for coarsely polishing both surfaces of wafers, interleaves wafers between lapping plates to remove irregularities on the wafer surfaces by rubbing them while draining grinding fluid containing abrasive grain.

The etching apparatus WF6 chemically processes both surfaces of wafers using acidic or alkaline etchant to remove mechanical damages due to processing by the above lapping apparatus. The heat treatment apparatus WF7 performs heat treatment for dissolving oxygen donors caused from the situation where oxygen atoms, which have been solved into the silicon single crystal during the growth thereof from a crucible of the single crystal pulling apparatus WF1, are coupled to act as donors thereby deviating the resistance value from the controlled value depending on certain dopants. The heat treatment concurrently serves to ease process-caused stresses and decrease crystal defects, etc.

The polishing apparatus WF8 performs mechano-chemical polishing (or Chemical Mechanical Polishing: CMP) using colloidal silica liquid in order to remove irregularities on the wafer surfaces thereby accomplishing mirror finishing with high flatness. The cleaning apparatus WF9 is to clear away any contamination due to the above precedence processes, and the inspecting apparatus WF10 comprises a flatness measuring device, a particle measuring device, and other devices.

The final process of the wafer manufacturing factory WF is provided with a stocker WF11 for temporarily storing wafers having passed the inspections by the inspecting apparatus WF10 with the purpose of production adjustment.

The cross sectional structure of the above-described wafer manufacturing factory WF is illustrated in FIG. 3. It is to be noted that the cross sectional structures of the device element forming factory DF and the device assembly factory AF are basically identical with the structure as shown.

The building of the wafer manufacturing factory WF comprises a working zone Z10 in which the above-described apparatuses WF 1 to WF 11 are arranged and the conveying apparatus V moves, a utility zone Z20 formed below the floor face Z11 of the working zone Z10 and provided therein with power supply equipments and environment conservation facilities etc. (not shown), and a chamber zone Z30 formed above the ceiling Z12 of the working zone Z10 and provided therein with an air conditioner Z31 for supplying external air after controlling the temperature thereof.

The floor face Z11 of working zone Z10 is comprised of grating panels or the like capable of ventilating air, and the ceiling face Z12 is provided thereon entirely with various filters Z32 such as HEPA filters and ULPA filters.

Note that a chemical removing machine CM may be additionally provided as illustrated in the same figure to chemically remove impurities arising in the working zone Z10 and other zones.

According to the above-described clean room structure, external air from outside is adjusted with regard to temperature and humidity by the air conditioner Z31 to be introduced into the working zone Z10 via the filters Z32, then flows from top to bottom within that working zone Z10, and is finally exhausted from the utility zone Z20. Such cleaned air according to the clean room also flows into the conveying zone Z1 connecting the wafer manufacturing factory WF with the device element forming factory DF and the conveying zone Z2 connecting the device element forming factory DF with the device assembly factory AF thereby to ensure the cleanliness within these conveying zones Z1 and Z2. Note that, if the conveying zone Z1 or Z2 is large or in other cases, then that conveying zone Z1 or Z2 may be provided as a clean room in itself (i.e. associated with the air conditioner Z31 and the like).

Hereinafter, the conveying apparatus will be described which is for sequentially conveying wafers having been sliced by the slicing apparatus WF3 along the beveling apparatus WF4, lapping apparatus WF5, etching apparatus WF6, heat treatment apparatus WF7, polishing apparatus WF8, cleaning apparatus WF9, and inspecting apparatus WF10 in this order.

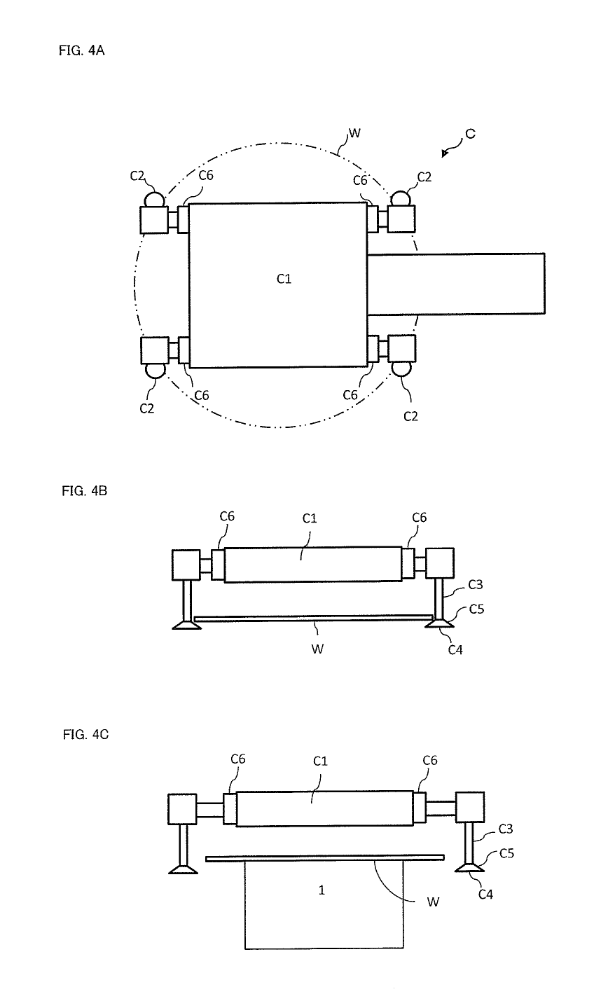

FIG. 4A is a plan view illustrating a chuck of the conveying apparatus V shown in FIG. 2, FIG. 4B is a side elevational view for FIG. 4A, and FIG. 4C is a side elevational view for explaining the handling operation of that chuck.

The conveying apparatus V according to the present embodiment moves along a rail R continuously provided from the zone within which the slicing apparatus WF3 of the wafer manufacturing factory WF is placed, via the zone in which the stocker WF11 is placed, to the zone within which a packing apparatus AF6 of the device assembly factory AF is placed as will be described later. The rail R for the conveying apparatus V may be provided at the ceiling of each factory WF, DF, AF or the floor face thereof. In the case of providing the rail R at the ceiling, the conveying apparatus V may be applicable which utilizes a linear motor to travel on the rail R or is suspended below the rail R. Also in the case of providing the rail R at the floor face, the conveying apparatus V may be applicable which comprises an autonomous moving robot or the like. In either case, the conveying apparatus V automatically moves in response to commands from a manufacturing management apparatus not shown.

The conveying apparatus V according to the present embodiment is for holding wafers by a chuck to convey them among the processes without storing the wafers in a conventional carrying case (so-called a cassette).

The chuck C according to the present embodiment comprises a hand member C1 which is at least movable up-and-down and forward-and backward and rotatable, and this hand member C1 is provided with four (at least three) hook members C2 extending downward. Each hook member C2 has an extending rod C3 and a flange portion C4 provided at the lower end of the extending rod C3, and the upper surface part of the flange portion C4 is formed as a taper face C5. In addition, the hand member C1 is provided with cylinders C6 in order for the hook members C2 to be movable to come close to or depart from one another.

When holding or releasing a wafer W by the chuck C structured as the above, the hand member C1 is moved to a position above the wafer W placed on the upper face of a wafer table 1, the hand member C1 is in turn moved downward in the status where the hook members C2 are opened, that is, the hook members C2 are departed from one another to be positioned at outside of the wafer W, and the downward moving is stopped in the status where each hook member C2 is lateral to the wafer W. FIG. 4C illustrates this situation.

Thereafter, the hook members C2 are closed, that is, the hook members C2 are moved to come close to one another so as to contact the circumference edge of the wafer W. At this time, the wafer W is avoided from being contacted with the extending rods C3 of hook members C2, and the wafer W is held by the hook members C2 in the status of being placed on the taper faces C5 of flange portions C4. The hook members C2 are moved upward in this situation thereby allowing the chuck C to hold the wafer W. Note that releasing the wafer F involves the reverse operation to the above.

The chuck C according to the present embodiment holds only the edge portion of wafer W and is avoided from holding a main surface having been polished or a main surface having been formed with device elements, thereby to ensure the cleanliness of the wafer W. Moreover, the wafer W in itself is not applied with active forces from the hook members C2 therefore being prevented from any deformation or breaking and cracking even though the wafer W is a heavy one such as a 450 mm wafer. As a consequence, stable handling may be performed even for a large diameter wafer W.

The conveying apparatus V is provided with a plurality of the above chucks C, and one conveying apparatus V holds a plurality of wafers and conveys them among the processes.

Referring again to FIG. 2, the device element forming factory DF according to the present embodiment is provided with various apparatuses for creating device elements, which constitute integrated circuits, to be embedded onto and/or into wafers having been polished. Representative examples of device element forming processes include a device element isolation process, an impurities diffusion process, a gate forming process, an interlayer/interconnection process, and an inspection process.

To this end, various apparatuses are arranged, such as a cleaning apparatus DF8, an oxidizing and diffusing apparatus DF9, an ion implanting apparatus DF10, a photolithography apparatus DF11, an etching apparatus DF12, a film forming apparatus DF13 and an inspecting apparatus DF14.

Wafers, which have been held and conveyed by the conveying apparatus V from the stocker WF11 arranged in the final process of the wafer manufacturing factory WF, are conveyed to a stocker DF1 arranged in the initial process of that device element forming factory DF to be temporarily stored. This stocker DF1 also functions as a buffer process for production adjustment in the device element forming factory DF.

Wafers stored in the stocker DF1 are held by the conveying apparatus V in response to commands from the manufacturing management apparatus and conveyed to be subjected to a processing by each of various apparatuses DF8 to DF14 while being temporarily stored in a plurality of stockers DF2 to DF7 arranged corresponding to respective apparatuses DF8 to DF14. Note that the inspecting apparatus DF14 is an apparatus for performing operation test on device elements created in terms of wafers.

Wafers having passed the inspections by the inspecting apparatus DF14 are held by the conveying apparatus V and conveyed to the device assembly factory AF via the conveying zone Z2 to be temporarily stored in a stocker AF1.

The device assembly factory AF is provided with a grinding apparatus AF2 for grinding wafers having been created with device elements, a dicing apparatus AF3 for dicing, a packaging apparatus AF4 for packaging, an inspecting apparatus AF5 for performing final inspection, and a packing apparatus AF6 for packing before shipping.

While the conveying apparatus V is provided with chucks C shown in FIG. 4A to FIG. 4C for the reason that the wafers are in the status as wafers before being conveyed to the dicing apparatus AF3, the conveying apparatus V may be provided with, for example, trays or the like for accommodating chips having been diced because wafers are to be diced into such chips after the dicing process in the dicing apparatus AF3 has been completed.

As described hereinbefore, according to the semiconductor manufacturing plant in the present embodiment, the wafer manufacturing factory WF and the device element forming factory DF are built abutting each other to immediately convey manufactured wafers to the device element forming factory thereby significantly decreasing the conveying time.

Moreover, the conveying of wafers are performed under the condition where one or more wafers are directly held by the conveying apparatus V without being stored in a conventional cassette, and therefore it is enable to convey wafers without breaking or cracking them even in the case of heavy wafers having more than 300 mm diameters, such as 450 mm wafers.

It is to be noted that the embodiments as explained above are described to facilitate understanding of the present invention and are not described to limit the present invention. Therefore, it is intended that the elements disclosed in the above embodiments include all design changes and equivalents to fall within the technical scope of the present invention.

What is claimed is:

1. A semiconductor manufacturing plant comprising:
a wafer manufacturing factory manufacturing a semiconductor wafer;
a device manufacturing factory provided abutting the wafer manufacturing factory via a conveying zone comprised of a clean room, the device manufacturing factory manufacturing a semiconductor device from the semiconductor wafer;
a conveying apparatus provided within the conveying zone and holding the semiconductor wafer manufactured in the wafer manufacturing factory to convey the semiconductor wafer to the device manufacturing factory without storing the semiconductor wafer in a carrying case.

2. The semiconductor manufacturing plant as recited in claim 1, wherein
the semiconductor wafer is a 450 mm wafer.

3. The semiconductor manufacturing plant as recited in claim 1, wherein
the wafer manufacturing factory and the device manufacturing factory are different buildings.

4. The semiconductor manufacturing plant as recited in claim 1, wherein
the conveying apparatus holds only an edge portion of the semiconductor wafer.

5. The semiconductor manufacturing plant as recited in claim 1, further comprising
a storage temporarily storing the semiconductor wafer within at least either one of a final process in the wafer manufacturing factory or an initial process in the device manufacturing factory.

6. The semiconductor manufacturing plant as recited in claim 1, wherein
the device manufacturing factory comprises: a device element forming factory creating semiconductor elements to the semiconductor wafer; and a device assembly factory manufacturing semiconductor devices from the wafer having been created with the semiconductor elements, and the device element forming factory and the device assembly factory are provided abutting each other via a conveying zone comprised of a clean room.

7. The semiconductor manufacturing plant as recited in claim 5, wherein
the conveying apparatus automatically conveys the semiconductor wafer and automatically stores the semiconductor wafer in the storage in response to a command from a manufacturing management apparatus.

8. A wafer manufacturing factory manufacturing a semiconductor wafer,
the wafer manufacturing factory being provided abutting a device manufacturing factory via a conveying zone comprised of a clean room, the device manufacturing factory manufacturing a semiconductor device from the semiconductor wafer,
the wafer manufacturing factory comprising a conveying apparatus provided within the conveying zone and holding the semiconductor wafer manufactured in the wafer manufacturing factory to convey the semiconductor wafer to the device manufacturing factory without storing the semiconductor wafer in a carrying case.

9. The wafer manufacturing factory as recited in claim 8, wherein
the conveying apparatus automatically conveys the semiconductor wafer in response to a command from a manufacturing management apparatus.

10. The wafer manufacturing factory as recited in claim 8, wherein
the semiconductor wafer is a 450 mm wafer.
